(19) United States
(12) Patent Application Publication
(10) Pub. No.: US 2026/0190489 A1
(43) Pub. Date: Jul. 2, 2026

(54) DISPLAY PANEL AND DISPLAY DEVICE

(71) Applicant: Hubei Yangtze Industrial Innovation Center of Advanced Display Co., LTD., Wuhan (CN)

(72) Inventor: Weiwei YANG, Wuhan (CN)

(21) Appl. No.: 19/073,451

(22) Filed: Mar. 7, 2025

(30) Foreign Application Priority Data
Dec. 31, 2024 (CN) 202411982833.2

(51) Int. Cl. H10D 86/40; H10D 86/60

(52) U.S. Cl. CPC H10D 86/443; H10D 86/60

(57) ABSTRACT

A display panel and a display device are provided. The display panel includes a substrate, an active layer, and a gate. The active layer includes active branches sequentially arranged along a first direction. The active branch extends along a second direction. The first direction and the second direction intersect. The active branch includes a source terminal, a drain terminal, and a channel region between the source terminal and the drain terminal. The source terminal is connected to a source. The drain terminal is connected to a drain. The gate extends along the second direction. The active branches at least include a first active branch and a second active branch. A direction from the source terminal to the drain terminal of the first active branch is the second direction, and a direction from the source terminal to the drain terminal of the second active branch is opposite to the second direction.

### CROSS-REFERENCE TO RELATED APPLICATION

The present disclosure claims priority of Chinese Patent Application No. 202411982833.2, filed on Dec. 31, 2024, the entire content of which is hereby incorporated by reference.

### FIELD OF THE DISCLOSURE

The present disclosure generally relates to the field of display equipment technology and, more particularly, relates to a display panel and a display device.

### BACKGROUND

With continuous development of science and technology, more and more display devices are widely used in people's daily life and work. Display devices have brought great convenience to people's daily life and work, and have become indispensable tools for people. A main component of a display device for realizing display functions is a display panel.

Pixels in a display panel need to be controlled by pixel circuits for image display. A pixel circuit may include a plurality of transistors that are interconnected. To improve the driving capability of an existing transistor, the channel size of the transistor may need to be increased to increase the output current. The larger output current may cause a large amount of heat generated during the operation of the transistor, and the performance of the transistor may thus be affected.

### SUMMARY

One aspect of the present disclosure includes a display panel. The display panel includes a substrate, an active layer, and a gate. The active layer is disposed over a surface of the substrate, and the active layer includes a plurality of active branches sequentially arranged along a first direction. An active branch of the plurality of active branches extends along a second direction, and the first direction and the second direction intersect, and each are parallel to a plane where the substrate is located. The active branch includes a source terminal, a drain terminal, and a channel region located between the source terminal and the drain terminal. The source terminal is connected to a source, and the drain terminal is connected to a drain. The gate extends along the second direction, and in a direction perpendicular to the plane where the substrate is located, the gate and the channel region of the active branch have an overlapping portion. The plurality of active branches at least includes a first active branch and a second active branch. A direction from the source terminal to the drain terminal of the first active branch is the second direction, and a direction from the source terminal to the drain terminal of the second active branch is an opposite direction of the second direction.

Another aspect of the present disclosure includes a display device. The display device includes a display panel. The display panel includes a substrate, an active layer, and a gate. The active layer is disposed over a surface of the substrate, and the active layer includes a plurality of active branches sequentially arranged along a first direction. An active branch of the plurality of active branches extends along a second direction, and the first direction and the second direction intersect, and each are parallel to a plane where the substrate is located. The active branch includes a source terminal, a drain terminal, and a channel region located between the source terminal and the drain terminal. The source terminal is connected to a source, and the drain terminal is connected to a drain. The gate extends along the second direction, and in a direction perpendicular to the plane where the substrate is located, the gate and the channel region of the active branch have an overlapping portion. The plurality of active branches at least includes a first active branch and a second active branch. A direction from the source terminal to the drain terminal of the first active branch is the second direction, and a direction from the source terminal to the drain terminal of the second active branch is an opposite direction of the second direction.

Other aspects of the present disclosure may be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of a display panel;

FIG. 2 illustrates a top view of a transistor in a display panel consistent with the disclosed embodiments of the present disclosure;

FIG. 3 illustrates a cross-sectional view of a display panel shown in FIG. 2 taken along the A-A′ direction, consistent with the disclosed embodiments of the present disclosure;

FIG. 4 illustrates a cross-sectional view of a display panel shown in FIG. 2 taken along the B-B′ direction, consistent with the disclosed embodiments of the present disclosure;

FIG. 5 illustrates a top view of an active layer consistent with the disclosed embodiments of the present disclosure;

FIG. 6 illustrates a top view of another active layer consistent with the disclosed embodiments of the present disclosure;

FIG. 7 illustrates a top view of another active layer consistent with the disclosed embodiments of the present disclosure;

FIG. 8 illustrates a cross-sectional view of a display panel along an extension direction of a first active branch, consistent with the disclosed embodiments of the present disclosure;

FIG. 9 illustrates a cross-sectional view of a display panel along an extension direction of a second active branch, consistent with the disclosed embodiments of the present disclosure;

FIG. 10 illustrates a cross-sectional view of a display panel along a length direction of an active branch, consistent with the disclosed embodiments of the present disclosure;

FIG. 11 illustrates a top view of a transistor in another display panel consistent with the disclosed embodiments of the present disclosure;

FIG. 12 illustrates a cross-sectional view of a display panel shown in FIG. 11 taken along the C-C′ direction, consistent with the disclosed embodiments of the present disclosure;

FIG. 13 illustrates a cross-sectional view of a display panel shown in FIG. 11 taken along the D-D′ direction, consistent with the disclosed embodiments of the present disclosure;

FIG. 14 illustrates a top view of a transistor in another display panel consistent with the disclosed embodiments of the present disclosure;

FIG. 15 illustrates a cross-sectional view of a display panel shown in FIG. 14 taken along the E-E′ direction, consistent with the disclosed embodiments of the present disclosure;

FIG. 16 illustrates a cross-sectional view of a display panel shown in FIG. 14 taken along the F-F′ direction, consistent with the disclosed embodiments of the present disclosure;

FIG. 17 illustrates a top view of an active branch, consistent with the disclosed embodiments of the present disclosure;

FIG. 18 illustrates a top view of another active branch, consistent with the disclosed embodiments of the present disclosure;

FIG. 19 illustrates a partial cross-sectional view of a drain region of a display panel consistent with the disclosed embodiments of the present disclosure;

FIG. 20 illustrates a partial cross-sectional view of a drain region of another display panel consistent with the disclosed embodiments of the present disclosure;

FIG. 21 illustrates a schematic principle diagram of a connection between an active branch and an active layer in a display panel consistent with the disclosed embodiments of the present disclosure;

FIG. 22 illustrates a schematic principle diagram of a connection between an active branch and an active layer in another display panel consistent with the disclosed embodiments of the present disclosure;

FIG. 23 illustrates a top view of an active layer of a display panel consistent with the disclosed embodiments of the present disclosure; and

FIG. 24 illustrates a schematic structural diagram of a display device consistent with the disclosed embodiments of the present disclosure.

The above drawings include the following reference numerals: 10—active layer; 101—active branch; 11—source; 111—first source trace; 112—second source trace; 12—drain; 121—first drain trace; 122—second drain trace; 131—source terminal; 132—drain terminal; 133 channel region; 14—gate; 15—substrate; 161—first conductive via; 162—second conductive via; 171—first active branch; 172—second active branch; 181—first active branch group; 182—second active branch group; 19—insulation layer; 191—first insulation layer; 192—second insulation layer; 201—first trace; 202—second trace; 203—third trace; 211—first comb teeth; 212—second comb teeth; 22—heat—conducting metal portion; 23—heat-conducting structure; 24—light-shielding metal layer; 25—display panel; Y-first direction; X-second direction; Z-third direction; M1—first metal layer; M2—second metal layer; and M3—third metal layer.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Technologies, methods, and equipment known to those of ordinary skill in relevant fields may not be discussed in detail, but where appropriate, these technologies, methods, and equipment should be regarded as part of the present disclosure.

It should be noted that in the present disclosure, when an element (such as a layer, a film, a region, or a substrate) is referred to as being “over” another element, the element may be directly on the other element, or intervening elements may be present. In addition, in the present disclosure, when an element is described as being “connected” to another element, the element may be “directly connected” to the other element, or “connected” to the other element through a third element.

Directional or positional relationships indicated by terms, such as “upper”, “lower”, “top”, “bottom”, “inner”, and “outer”, are based on the directional or positional relationships shown in the drawings. These terms are only for convenience of description, and for simplifying the description. These terms do not indicate or imply that the devices or elements referred to must have a specific orientation, be constructed and operate in a specific orientation. These terms should not be understood as a limit to the present disclosure.

It should be noted that in the present disclosure, relational terms such as “first” and “second” are only used to distinguish one entity or operation from another entity or operation, and do not necessarily require or imply that such actual relationship or sequence exists between these entities or operations. Terms “comprise”, “include” or any other variations thereof are intended to cover a non-exclusive inclusion. A process, method, article, or apparatus that includes a series of elements includes not only the series of elements, but also other elements not expressly listed, or elements inherent to such a process, method, article, or apparatus. Without further limitation, an element defined by a statement like “comprises a . . . ” does not exclude the presence of additional identical elements in a process, method, article, or apparatus that includes the foregoing element. In the present disclosure, that layer A and layer B are “disposed on a same layer” means that layer A and layer B are made of a same material and in a same process.

Reference will now be made in detail to embodiments of the present disclosure, which are illustrated in the accompanying drawings. Similar labels and letters designate similar items in the drawings. Once an item is defined in one drawing, the item may not be defined and discussed in subsequent drawings.

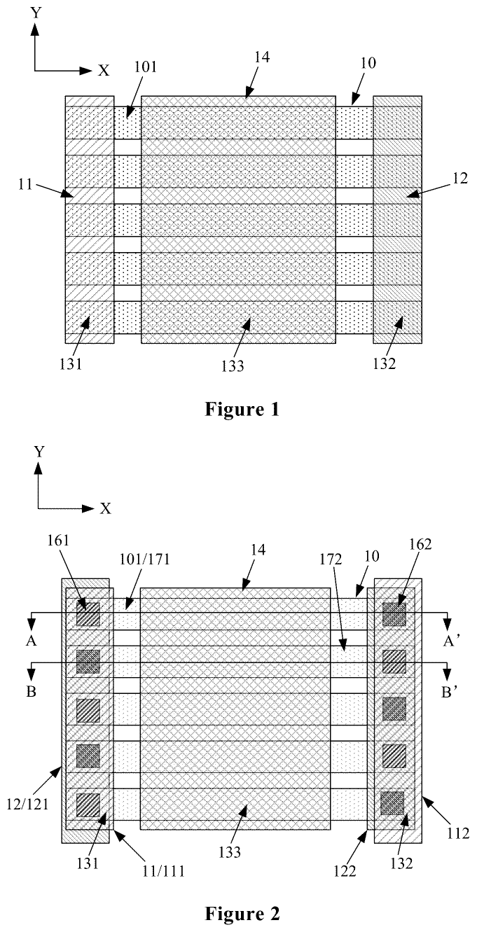

Driving capability of a transistor may be improved by increasing the size of the transistor to increase output current of the transistor. Larger driving current may cause the transistor to generate more heat during operation. When the high heat may not be dissipated in time, the switching speed, power consumption, and efficiency of the transistor may be affected. FIG. 1 illustrates a schematic structural diagram of a display panel. As shown in FIG. 1, to reduce the heat generated by a transistor, the transistor may be divided into a plurality of sub-transistors.

FIG. 1 shows a top view structure of a transistor in a display panel. As shown in FIG. 1, the transistor includes: an active layer 10, a source 11 disposed over the active layer 10, a drain 12 disposed over the active layer 10, and a gate 14 disposed over the active layer 10.

The active layer 10 includes a plurality of active branches 101 sequentially arranged along a first direction Y. The active branch 101 include a source terminal 131, a channel region 133 and a drain terminal 132 sequentially arranged along a second direction X.

The source 11 is connected to the source terminal 131 of each active branch 101. The drain 12 is connected to the drain terminal 132 of each active branch 101. The gate 14 has an overlapping portion with the channel region 133 of each active branch 101.

In the configuration shown in FIG. 1, the active layer 10 of the transistor is divided into the plurality of active branches 101. Each active branch 10 may form a sub-transistor. As such, the transistor may be divided into a plurality of sub-transistors, and the high-temperature area of the transistor may thus be dispersed. Accordingly, heat in the transistor may be well dissipated, and the heat dissipation effect may be improved.

Dividing a transistor into a plurality of sub-transistors may improve the heat dissipation effect of the transistor to a certain extent. However, since the current in the transistor is transmitted from the source terminal 131 to the drain terminal 132, and the drain terminal 132 operates as the current output terminal, the heat in the transistor may be concentrated at the drain terminal 132. In the configuration shown in FIG. 1, the drain terminals 132 each are located on a same side of the channel region 133. As such, the heat of each sub-transistor may be concentrated on a same side, and the heat dissipate efficiency of the transistor may thus be affected. Accordingly, the performance of the transistor may be affected, and the image display quality of the display panel may thus be affected.

To solve the above problems, the present disclosure provides a display panel. The display panel includes: a substrate, an active layer disposed over a surface of the substrate, and a gate extending along a second direction.

The active layer includes a plurality of active branches sequentially arranged in a first direction. The active branches extend along the second direction. The first direction and the second direction intersect, and each are parallel to a plane where the substrate is located. The active branch includes a source terminal, a drain terminal, and a channel region between the source terminal and the drain terminal. The source terminal is connected to the source, and the drain terminal is connected to the drain.

In a direction perpendicular to the plane where the substrate is located, the gate and the channel region of the active branch have an overlapping portion.

The plurality of active branches at least includes a first active branch and a second active branch. The direction from the source terminal to the drain terminal of the first active branch is the second direction. The direction from the source terminal to the drain terminal of the second active branch is the opposite direction of the second direction.

In a display panel provided by the present disclosure, the active layer is divided into a plurality of active branches. Each active branch may form a sub-transistor. As such, the self-heating of the transistor may be reduced, and the heat generated when the transistor is in operation may be reduced. Accordingly, the impact of excessive heat on transistor performance may be avoided.

In addition, the plurality of active branches of the active layer includes a first active branch and a second active branch. The direction from the source terminal to the drain terminal in the first active branch and the direction from the source terminal to the drain terminal in the second active branch are opposite, and each are parallel to the second direction. As such, in the second direction, the drain terminals of at least two sub-transistors may be located on different sides of the channel region. As a result, the heat concentration problem caused by the drain terminals of the sub-transistors each being concentrated on a same side of the channel region may be avoided, and the heat dissipation of the transistor may be improved. Accordingly, the influence of excessive heat on the performance of transistors may be avoided, and the image display quality may be improved.

To make the above-mentioned purposes, features and advantages of the present disclosure obvious and easy to understand, detailed descriptions are given below with reference to accompanying drawings and specific embodiments.

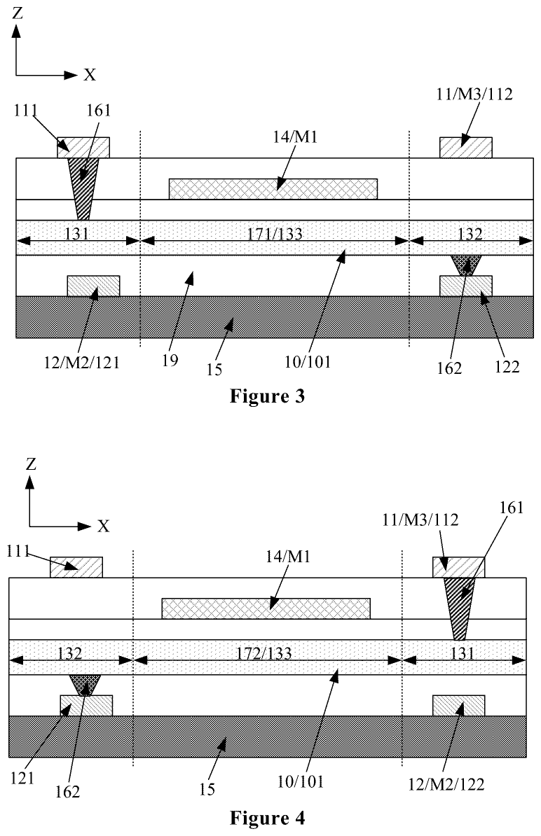

FIG. 2 illustrates a top view of a transistor in a display panel consistent with the disclosed embodiments of the present disclosure. FIG. 3 illustrates a cross-sectional view of a display panel shown in FIG. 2 taken along the A-A′ direction. FIG. 4 illustrates a cross-sectional view of a display panel shown in FIG. 2 taken along the B-B′ direction. Referring to FIGS. 2-4, the display panel includes: a substrate 15, an active layer 10, and a gate 14.

The active layer 10 is disposed over the surface of the substrate 15. The active layer 10 includes a plurality of active branches 101 sequentially arranged in a first direction Y. The active branches 101 extend along a second direction X. The first direction Y and the second direction X intersect, and each are parallel to the plane where the substrate 15 is located. The active branch 101 includes a source terminal 131, a drain terminal 132, and a channel region 133 located between the source terminal 131 and the drain terminal 132. The source terminal 131 is connected to the source 11, and the drain terminal 132 is connected to the drain 12.

The gate 14 extends along the second direction X. In a direction perpendicular to the plane where the substrate 15 is located, the gate 14 and the channel region 133 of the active branch 101 have an overlapping portion.

The plurality of active branches 101 includes at least a first active branch 171 and a second active branch 172. The direction from the source terminal 131 to the drain terminal 132 of the first active branch 171 is the second direction X. The direction from the source terminal 131 to the drain terminal 132 of the second active branch 172 is the opposite direction of the second direction X.

Optionally, the first direction Y and the second direction X are perpendicular to each other. The direction perpendicular to the plane where the substrate 15 is located is set as a third direction Z. The third direction Z is perpendicular to the first direction Y and the second direction X.

In the present disclosure, the active layer 10 of a transistor is divided into a plurality of active branches 101. Based on the plurality of active branches 101, a large transistor may be divided into a plurality of small sub-transistors, and one active branch 101 may form one sub-transistor. By dividing a large transistor into a plurality of small sub-transistors, the self-heating of the transistor may be reduced, the heat generated when the transistor is in operation may be reduced, and the impact on the performance of the transistor due to excessive heat may be avoided.

Furthermore, the plurality of active branches 101 of the active layer 10 at least includes a first active branch 171 and a second active branch 172. The direction from the source terminal 131 to the drain terminal 132 in the first active branch 171 and the direction from the source terminal 131 to the drain terminal 132 in the second active branch 172 are opposite, and each are parallel to the second direction X. As such, in the second direction X, the drain terminals 132 of at least two sub-transistors may be located on different sides of the channel region 133. Since the drain terminals 132 of at least two active branches 101 may be dispersed on different sides of the channel region 133, the dispersion degree of the drain terminals 132 in the active layer 10 may be improved. Accordingly, the heat concentration problem caused by the drain terminals 132 of the plurality of sub-transistors being concentrated on a same side of the channel region 133 may be avoided.

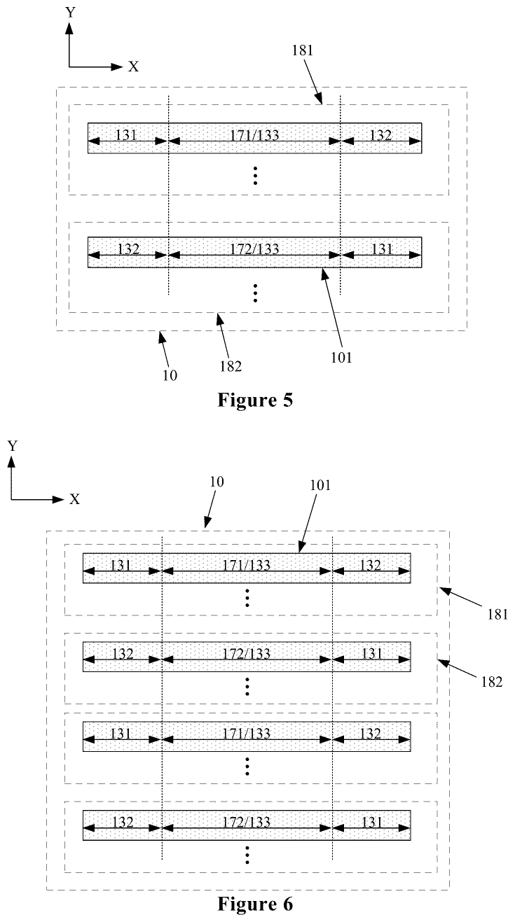

FIG. 5 illustrates a top view of an active layer consistent with the disclosed embodiments of the present disclosure. Referring to FIG. 5, in the first direction Y, the plurality of active branches 101 includes a first active branch group 181 and a second active branch group 182 arranged in sequence. The first active branch group 181 includes at least one first active branch 171, and the second active branch group 182 includes at least one second active branch 172. In this approach, the quantity of active branches 101 in the first active branch group 181 and the quantity of active branches 101 in the second active branch group 182 may be same or different.

In the approach shown in FIG. 5, along the first direction Y, the plurality of active branches 101 in the active layer 10 may be divided into two groups. The two groups may be respectively taken as the first active branch group 181 and the second active branch group 182. The active branches 101 in the first active branch group 181 include first active branches 171, and the active branches 101 in the second active branch group 182 include second active branches 172. As such, the drain terminals of the active branches 101 in the first active branch group 181 are each located on a side of the channel region 133 facing the second direction X. The drain terminals of the active branches 101 in the second active branch group 182 are each located on a side of the channel region 133 away from the second direction X. Accordingly, the drain terminals 132 of the active branches 101 may not be gathered on a same side of the channel region 133, the dispersion degree of the drain terminals 132 may be increased, and the heat dissipation effect may be improved.

FIG. 6 illustrates a top view of another active layer consistent with the disclosed embodiments of the present disclosure. Referring to FIG. 6, the plurality of active branches 101 include: the first active branch groups 181 and the second active branch groups 182 that are alternately arranged along the first direction Y. In this way, the plurality of active branches 101 in the active layer 10 may be divided into at least three groups. Of any two adjacent groups, one is the first active branch group 181 and the other is the second active branch group 182. Compared with the approach shown in FIG. 5, the approach shown in FIG. 6 may further improve the dispersion degree of the drain terminals 132, and may further improve the heat dissipation effect.

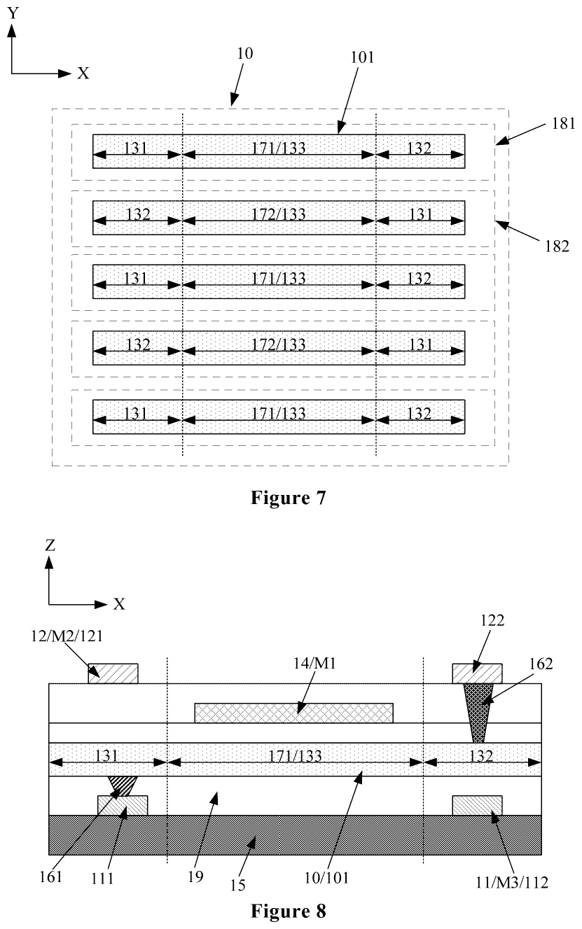

When the active layer 10 includes the first active branch group 181 and the second active branch group 182, the first active branch group 181 and the second active branch group 182 may each include one active branch. FIG. 7 illustrates a top view of another active layer consistent with the disclosed embodiments of the present disclosure. The first active branch 171 and the second active branch 172 in the active layer 10 may be distributed in a way shown in FIG. 7.

Referring to FIG. 7, the first active branch group 181 and the second active branch group 182 each include one active branch. On a same side of the channel region 133, along the first direction Y, the source terminals 131 and the drain terminals 132 of the active branches 101 are arranged alternately. FIG. 8 illustrates a cross-sectional view of a display panel along an extension direction of a first active branch, consistent with the disclosed embodiments of the present disclosure. As shown in FIG. 8, on the left side of the channel region 133, along the first direction Y, the source terminals 131 and the drain terminals 132 of the active branches 101 are arranged alternately. On the right side of the channel region 133, along the first direction Y, the source terminals 131 and the drain terminals 132 of the active branches 101 are arranged alternately. This approach may maximize the dispersion degree of the drain terminals 132, and may better improve the heat dissipation effect.

In the approach shown in FIGS. 2 to 4, the first active branches 171 and the second active branches 172 may be alternately arranged along the first direction Y. The active branches 101 in the active layer 10 may be arranged in a way as shown in FIG. 7.

It should be noted that the quantity of the active branches 101 in the active layer 10 may be set to any number greater than 1 according to requirements, such as 2, 3 or more. The present disclosure does not limit a specific quantity of active branches 101 in the active layer 10.

In one embodiment, as shown in FIGS. 2-4, the gate 14 is disposed on the first metal layer M1, the drain 12 is disposed on the second metal layer M2, the source 11 is disposed on the third metal layer M3, and the active layer 10 is disposed between the second metal layer M2 and the third metal layer M3. The drain 12 includes a first drain trace 121 and a second drain trace 122 sequentially distributed along the second direction X. The source 11 includes a first source trace 111 and a second source trace 112 sequentially distributed along the second direction X. In a direction parallel to the plane where the substrate is located, the gate 14 is disposed between the first drain trace 121 and the second drain trace 122, and between the first source trace 111 and the second source trace 112. In the first active branch 171, the source terminal 131 is connected to the first source trace 111, and the drain terminal 132 is connected to the second drain trace 122. In the second active branch 172, the source terminal 131 is connected to the second source trace 112, and the drain terminal 132 is connected to the first drain trace 121.

In the approach shown in FIGS. 2 to 4, the source 11 and the drain 12 may be prepared from two metal layers respectively. The source 11 and the drain 12 are respectively located on opposite sides of the active layer 10. The source 11 and the drain 12 each have two traces. In one embodiment, the drain terminals 132 of at least two active branches 101 are located on different sides of the channel region 133, the source terminal 131 of each active branch 101 are connected to the source 11, and the drain terminal 132 of each active branch 101 is connected to the drain 12. As such, the dispersion of the drain terminals 132 may be improved. In addition, in each sub-transistor, the source terminal and the source may be correspondingly connected, and the drain terminal and the drain may be correspondingly connected.

In one embodiment, along the third direction Z, insulation layers 19 may be respectively disposed between adjacent metal layers and between the active layer 10 and the adjacent metal layer to prevent short circuit problems.

In one embodiment, the first metal layer M1 may be disposed between the second metal layer M2 and the active layer 10. In this way, the first metal layer M1 and the insulation layer 19 covered by the surface of the first metal layer M1 may increase the vertical spacing between the drain terminal 132 and the drain 12. As such, the heat transfer distance from the drain terminal 132 to the drain 12 may be increased, and heat may not be transferred from the drain terminal 132 to the drain 12 timely.

As shown in FIGS. 3 and 4, in one embodiment, to make the heat in the drain terminal 132 be quickly transferred to the drain 12, the first metal layer M1 may be disposed between the third metal layer M3 and the active layer 10. In this way, the first metal layer M1 and the insulation layer 19 covered by the surface of the first metal layer M1 may be prevented from increasing the heat transfer distance from the drain terminal 132 to the drain 12. As such, heat may be quickly transferred from the drain terminal 132 to the drain 12. Accordingly, heat may be quickly dissipated to other areas through the drain 12, and heat dissipation efficiency may be improved.

In one embodiment, as shown in FIGS. 3 and 4, the second metal layer M2 is disposed between the substrate 15 and the active layer 10. Above the transistors formed by the source, drain and active layer, structures such as pixels and a cover plate of the display panel may be disposed. These structures may affect the upward conduction of heat. In this way, the second metal layer M2 is disposed on the side of the active layer 10 facing the substrate 15, such that the drain 12 may be closer to the bottom of the substrate 15. The heat conduction path toward the bottom of the substrate 15 may be shortened, such that more heat may be conducted toward the side of the drain 12. In addition, the heat conducted from the drain terminal 132 to the drain 12 may be quickly dissipated to the outside of the display panel through the bottom of the substrate 15. Accordingly, the heat dissipation efficiency may be improved.

In one embodiment, the gate 14 is disposed in the first metal layer M1, the drain 12 is disposed in the second metal layer M2, and the source 11 is disposed in the third metal layer M3. The drain 12 includes a first drain trace 121 and a second drain trace 122 sequentially arranged along the second direction X, and the source 11 includes a first source trace 111 and a second source trace 112 sequentially arranged along the second direction X. In this case, the source terminal 131 may be connected to the source 11 through a first conductive via 161, and the drain terminal 132 may be connected to the drain 12 through a second conductive via 162.

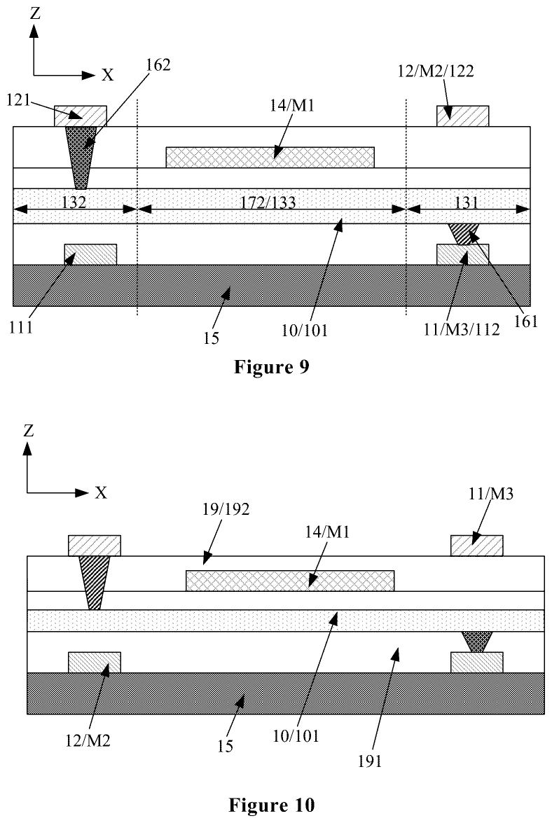

FIG. 8 illustrates a cross-sectional view of a display panel along an extension direction of a first active branch, consistent with the disclosed embodiments of the present disclosure. FIG. 9 illustrates a cross-sectional view of a display panel along an extension direction of a second active branch, consistent with the disclosed embodiments of the present disclosure. Referring to FIGS. 8 and 9, the active branch 101 extends along the second direction X, and the second direction X is a length direction of the active branch 101. As such, the length directions of the first active branch 171 and the second active branch 172 each are the second direction X.

In the display panel shown in FIGS. 8 and 9, the second metal layer M2 is disposed on a side of the active layer 10 away from the substrate 15. In this way, the drain 12 may be closer to the pixels disposed above, and the spacing between the drain 12 and the pixels may thus be shortened. In a display panel, a pixel needs to be connected to the drain of a corresponding transistor such that a data signal may be provided to the pixel through the transistor. In this configuration, since the spacing between the pixel and the drain 12 of the transistor connected to the pixel may be shortened, the circuit connection between the pixel and the transistor may be easy, and the layout and trace design in the display panel may be flexible.

In one embodiment, as shown in FIGS. 3 and 4, or as shown in FIGS. 8 and 9, in the direction perpendicular to the plane where the substrate 15 is located, the first source trace 111 is vertically opposite to the first drain trace 121, and the second source trace 112 is vertically opposite to the second drain trace 122. In this way, the drain trace in the second metal layer M2 and the source trace in the third metal layer M3 may be vertically opposed to each other. As such, the difficulty of the alignment design of the metal layers in the display panel and the layout design of the metal layers in the display panel may be reduced, and the manufacturing difficulty of the display panel may be reduced.

FIG. 10 illustrates a cross-sectional view of a display panel along a length direction of an active branch, consistent with the disclosed embodiments of the present disclosure. In the display panel shown in FIG. 10, at least one first insulation layer 191 is disposed between the second metal layer M2 and the active layer 10, and at least one second insulation layer 192 is disposed between the third metal layer M3 and the active layer 10. The thermal conductivity of the first insulation layer 191 is greater than the thermal conductivity of the second insulation layer 192.

In one embodiment, the thermal conductivity of the first insulation layer 191 is set to be greater than the thermal conductivity of the second insulation layer 192. As such, the heat in the drain terminal 132 may be transferred toward the second metal layer M2 through the first insulation layer 191 with a larger thermal conductivity. The heat in the drain terminal 132 may be transmitted to other areas away from the drain terminal 132 based on the second metal layer M2. Accordingly, heat accumulation in the drain terminal 132 may be avoided, and the heat dissipation effect of the drain terminal 132 may be improved.

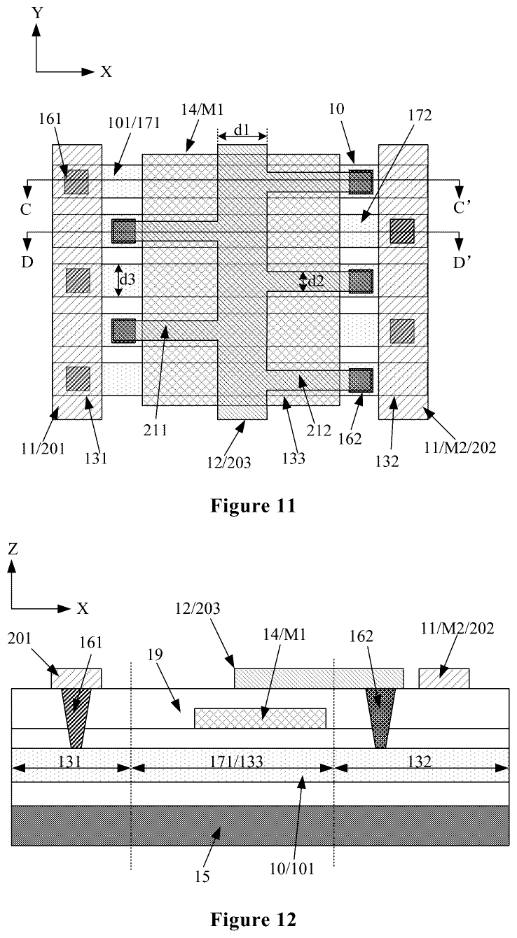

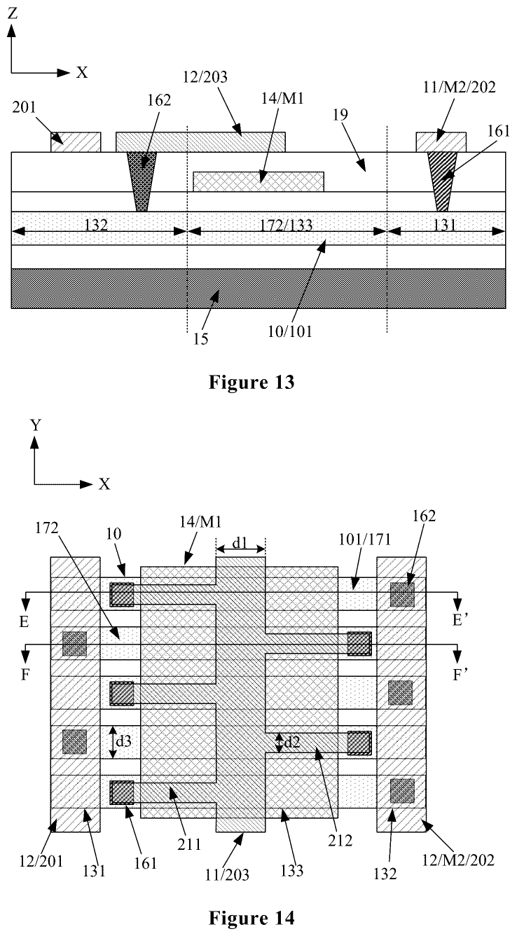

FIG. 11 illustrates a top view of a transistor in another display panel consistent with the disclosed embodiments of the present disclosure. FIG. 12 illustrates a cross-sectional view of a display panel shown in FIG. 11 taken along the C-C′ direction. FIG. 13 illustrates a cross-sectional view of a display panel shown in FIG. 11 taken along the D-D′ direction. In the display panel shown in FIGS. 11-13, the gate 14 is disposed on the first metal layer M1, and the source 11 and the drain 12 each are disposed on the second metal layer M2. One of the source 11 and the drain 12 includes a first trace 201 and a second trace 202 arranged in sequence in the second direction X, and the other includes a third trace 203 located between the first trace 201 and the second trace 202. In a direction parallel to the plane where the substrate 15 is located, the gate 14 is disposed between the first trace 201 and the second trace 202. Each source terminal 131 is connected to the source 11 through a first conductive via 161, and each drain terminal 132 is connected to the drain 12 through a second conductive via 162.

As shown in FIGS. 11 to 13, when the source 11 includes the first trace 201 and the second trace 202, the source terminal 131 of the first active branch 171 is connected to the first trace 201, and the source terminal 131 of the second active branch 172 is connected to the second trace 202. Each drain terminal 132 is connected to the third trace 203. The source terminal 131 of the first active branch 171 is connected to the first trace 201 through the corresponding first conductive via 161. The source 131 of the second active branch 172 is connected to the second trace 202 through the corresponding first conductive via 161. Each drain terminal 132 is connected to the third trace 203 through the corresponding second conductive via 162.

In the approach shown in FIGS. 11-13, at least two drain terminals 132 may be located on different sides of the channel region 133 to improve the dispersion of the drain terminals 132 and improve the heat dissipation effect. In addition, the source 11 and the drain 12 may be simultaneously prepared through a same second metal layer M2. As such, the thickness of the panel may be reduced, the preparation process may be simplified, and the preparation cost may be reduced.

When the source 11 and the drain 12 are simultaneously prepared from the second metal layer M2, the drain 12 may include a first trace 201 and a second trace 202. The drain terminal 132 of the first active branch 171 is connected to the second trace 202, and the drain terminal 132 of the second active branch 172 is connected to the first trace 201. Each source terminal 131 is connected to the third trace 203. In this way, at least two drain terminals 132 may be located on different sides of the channel region 133. As such, the dispersion of the drain terminals 132 may be improved, and the heat dissipation effect may be improved. In addition, since the source 11 and the drain 12 may be simultaneously prepared from a same second metal layer M2, the thickness of the panel may be reduced, the preparation process may be simplified, and the preparation cost may be reduced.

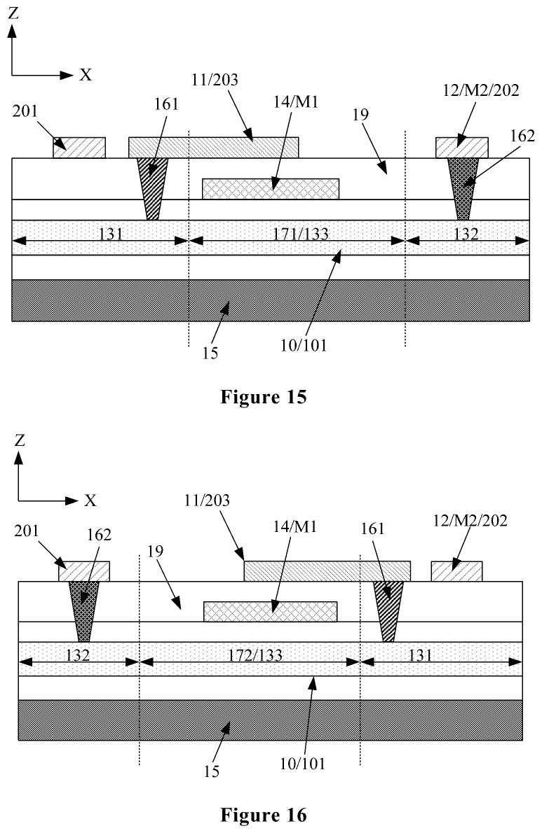

FIG. 14 illustrates a top view of a transistor in another display panel consistent with the disclosed embodiments of the present disclosure. FIG. 15 illustrates a cross-sectional view of a display panel shown in FIG. 14 taken along the E-E′ direction. FIG. 16 illustrates a cross-sectional view of a display panel shown in FIG. 14 taken along the F-F′ direction. When the drain 12 includes the first trace 201 and the second trace 202, the structure of the display panel may be as shown in FIGS. 14 to 16. The difference from the structure shown in FIGS. 11-13 is that in the display panel shown in FIGS. 14-16, the drain 12 includes the first trace 201 and the second trace 202, and the source 11 includes the third trace 203.

In the structure shown in FIGS. 14-16, each drain terminal 132 may be dispersedly arranged in the area corresponding to the first trace 201 and the second trace 202. Compared with the dispersion of the drain terminals 132 on the third trace 203 in FIG. 11, the drain terminals 132 may be dispersed in a larger area. Accordingly, the dispersion degree of the drain terminals 132 may be increased, and the heat dissipation effect may be improved.

As shown in FIG. 11 or FIG. 14, the third trace 203 includes a plurality of first comb teeth 211 arranged in sequence along the first direction Y on a side facing the first trace 201, and a plurality of second comb teeth 212 arranged in sequence along the first direction Y on a side facing the second trace 202.

As shown in FIG. 11, when the drain 12 includes the third trace 203, the drain terminal 132 of the first active branch 171 is connected to the third trace 203 through the second comb teeth 212, and the drain terminal 132 of the second active branch 172 is connected to the third trace 203 through the first comb teeth 211.

As shown in FIG. 14, when the source 11 includes the third trace 203, the source terminal 131 of the first active branch 171 is connected to the third trace 203 through the first comb teeth 211, and the source terminal 131 of the second active branch 172 is connected to the third trace 203 through the second comb teeth 212.

In one embodiment, the plurality of first comb teeth 211 arranged in sequence and the plurality of second comb teeth 212 arranged in sequence are respectively disposed on opposite sides of the third trace 203. Based on the comb-teeth structure of the third trace 203, the source terminal 131 and the drain terminal 132 may be correspondingly connected to the source 11 and the drain 12 of the same layer. Accordingly, the quantity of metal layers used by the source and drain may be decreased, the panel thickness may be reduced, the preparation process may be simplified, and the preparation cost may be reduced.

As shown in FIG. 11 or FIG. 14, the third trace 203 has a first width d1 in the second direction X. The first comb teeth 211 and the second comb teeth 212 each have a second width d2 in the first direction Y. The active branch 101 has a third width d3 in the first direction Y. Optionally, in one embodiment, d1>d3>d2.

The small current in the first comb teeth 211 and the second comb teeth 212 may converge into the third trace 203 to form large current. By setting d1>d3, the first comb teeth 211 and the second comb teeth 212 may have a smaller line width than the third trace 203. As such, the current transmission capacity of the third trace 203 may be improved.

When the channel width parameter of the active branch 101 is constant, that is, the width d3 is constant, by setting d3>d2, the area of the first comb teeth 211 and the second comb teeth 212 facing the gate 14 may be reduced. As such, the parasitic capacitance between the first comb teeth 211 and the gate 14, and the parasitic capacitance between the second comb teeth 212 and the gate 14, may be reduced. Accordingly, the influence of the parasitic capacitance on the transistor performance may be reduced.

In one embodiment, the third trace 203 is disposed on a side of the gate 14 away from the active layer 10. In a direction perpendicular to the plane where the substrate 15 is disposed, the third trace 203 and the gate 14 may have an overlapping portion. Based on the overlapping portion of the third trace 203 and the gate 14, the layout area of the third trace 203 and the gate 14 on the XY plane may be reduced. Accordingly, the transistor size may be reduced, the impact of the transistor size on the resolution of the display panel may be reduced.

In the display panel, an insulation layer 19 may be disposed between the third trace 203 and the gate 14. Optionally, the relative dielectric constant of the insulation layer 19 may be set to be less than 3.6, that is, the insulation layer 19 may be a low dielectric constant dielectric layer. According to the calculation principle of capacitance, capacitance is positively correlated with the dielectric constant of the insulation layer. Accordingly, a low dielectric constant dielectric layer may be used as the insulation layer 19 between the third trace 203 and the gate 14, to reduce the parasitic capacitance between the third trace 203 and the gate 14. As such, the impact of parasitic capacitance on transistor performance may be reduced.

In one embodiment, the insulation layer 19 is disposed between the third trace 203 and the gate 14, and the thickness of the insulation layer 19 is set to be not less than 500 nm. According to the calculation principle of capacitance, the capacitance is negatively correlated with the spacing between the two plates. Since the thickness of the insulation layer 19 is not less than 500 nm, the spacing between the two plates of the parasitic capacitance may be large. As such, the parasitic capacitance between the third trace 203 and the gate 14 may be reduced, and the influence of the parasitic capacitance on the transistor performance may be reduced.

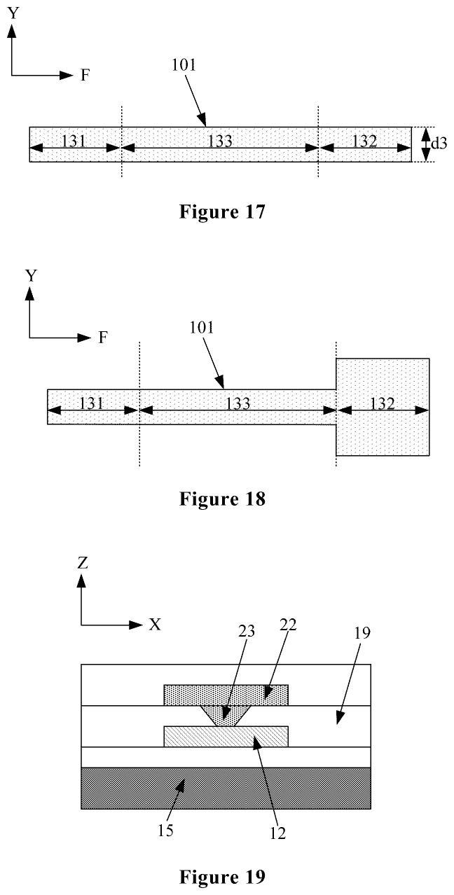

As described above, each active branch 101 may include a source terminal 131, a drain terminal 132, and a channel region 133 located between the source terminal 131 and the drain terminal 132. FIG. 17 illustrates a top view of an active branch, consistent with the disclosed embodiments of the present disclosure. In one embodiment, the structure of the active branch 101 may be as shown in FIG. 17.

In the structure shown in FIG. 17, along a fourth direction F, the active branch 101 includes a source terminal 131, a channel region 133, and a drain terminal 132 that are sequentially arranged. The fourth direction F is the second direction X or a direction opposite to the second direction X. When the fourth direction F is the second direction X, the active branch shown in FIG. 17 is the first active branch 171. When the fourth direction F is the opposite direction to the second direction X, the active branch shown in FIG. 17 is the second active branch 172.

In one embodiment, in the display panel, the width (i.e., the third width d3) of at least one active branch 101 is uniform along the fourth direction F. That is, the width of the active branch 101 at any position in the fourth direction F is equal to d3 or approximately equal to d3. Since the width of the active branch 101 may be uniform and unchanged, the fabrication difficulty of the active branch 101 may be reduced.

Optionally, in one embodiment, each active branch 101 may have a structure as shown in FIG. 17. As such, the widths of active branches 101 each are equal or approximately equal, and the widths of active branches 101 each are uniform and constant along the fourth direction F. In this way, each active branch 101 may be uniformly prepared based on a same width. Accordingly, patterning preparation of the active layer 10 may be realized, the difficulty of the preparation process of the active layer 10 may be reduced, and the difficulty of the preparation process of the display panel may thus be reduced. In some other embodiments, a part of the active branches 101 in the active layer 10 have a structure as shown in FIG. 17.

FIG. 18 illustrates a top view of another active branch, consistent with the disclosed embodiments of the present disclosure. As shown in FIG. 18, in one embodiment, in a same active branch 101, the source terminal 131 has a first area, and the drain terminal 132 has a second area. The second area is greater than the first area. Along the fourth direction F, the active branch 101 includes a source terminal 131, a channel region 133 and a drain terminal 132 which are sequentially arranged. The fourth direction F is the second direction X or an opposite direction to the second direction X. When the fourth direction F is the second direction X, the active branch shown in FIG. 17 is the first active branch 171. When the fourth direction F is the opposite direction of the second direction X, the active branch shown in FIG. 17 is the second active branch 172. In this way, since the area of the drain terminal 132 is larger than the area of the source terminal 131, the drain terminal 132 may have a larger area to conduct heat, thereby avoiding the concentration of heat in a small area due to a small area of the drain terminal 132. The drain terminal 132 with a larger area may also allow the heat to be transferred to the drain 12 at a faster speed, thereby preventing the heat from accumulating at the drain terminal 132. Accordingly, the heat dissipation effect of the transistor may be improved.

In one embodiment, in the display panel, at least one active branch 101 has a structure as shown in FIG. 18. The area of the drain terminal 132 is larger than the area of the source terminal 131. As such, the heat dissipation effect of the corresponding sub-transistor may be improved.

Optionally, in one embodiment, each active branch 101 has a structure as shown in FIG. 18. In this way, for each active branch 101, the area of the drain terminal 132 is larger than the area of the source terminal 131, and the sub-transistor corresponding to each active branch 101 may have a good heat dissipation effect. In some other embodiments, a part of the active branches 101 in the active layer 10 has a structure as shown in FIG. 18.

In one embodiment, the source 11 and the drain 12 have a same or approximately same area. As such, the source 11 and the drain 12 have a same area ratio. Accordingly, the patterning fabrication of the metal layer where the source 11 and the drain 12 are located may be realized, the difficulty of the patterning process of the metal layer may be reduced, and the difficulty of the manufacturing process of the display panel may thus be reduced.

When the areas of the source 11 and the drain 12 are same or approximately same, when the drain 12 includes a first drain trace 121 and a second drain trace 122 sequentially arranged along the second direction X, and the source 11 includes a first source trace 111 and a second source trace 112 sequentially arranged along the second direction X, the sum of the areas of the first drain trace 121 and the second drain trace 122 is equal to or approximately equal to the sum of the areas of the first source trace 111 and the second source trace 112. The first drain trace 121 and the second drain trace 122 may have a same line width, and may have a same or similar line width as the first source trace 111 and the second source trace 112. In this way, the difficulty of preparing the metal pattern structure where the source 11 and the drain 12 are located may be reduced, the difficulty of the preparation process of the source 11 and the drain 12 may be reduced, and the difficulty of the preparation process of the display panel may thus be reduced.

When the areas of the source 11 and the drain 12 are same or approximately same, when one of the source 11 and the drain 12 includes a first trace 201 and a second trace 202 sequentially arranged in the second direction X, and the other is a third line 203 located between the first trace 201 and the second trace 202, the sum of the areas of the first trace 201 and the second trace 202 may be equal to or approximately equal to the area of the third trace 203.

In one embodiment, the area of the drain 12 may be larger than the area of the source 11. Since the heat in the transistor is concentrated at the drain terminal 132, at least part of the heat at the drain terminal 132 may be conducted to the drain 12. The drain 12 made of metal may operate as a heat-distribution layer to disperse the heat. As such, heat concentration may be avoided, and the heat dissipation performance of the transistor may be improved. In this approach, the area of the drain 12 is set to be larger than the area of the source 11. With a larger area of the drain 12, the heat distribution effect of the drain 12 may be improved. The heat may be dispersed over a larger area to avoid heat concentration, and the heat dissipation effect may thus be improved.

FIG. 19 illustrates a partial cross-sectional view of a drain region of a display panel consistent with the disclosed embodiments of the present disclosure. In the display panel shown in FIG. 19, a plurality of metal layers is sequentially stacked on a same side of the substrate 15. One or more of the plurality of metal layers includes a heat-conducting metal portion 22, and the heat-conducting metal portion 22 is in thermal contact with the drain 12. The heat in the drain 12 may be transferred to other areas of the display panel through the heat-conducting metal portion 22. Accordingly, heat accumulation in the drain 12 may be avoided, the heat dissipation area may be increased, and the heat dissipation effect may be improved.

As shown in FIG. 19, the heat-conducting metal portion 22 and the drain 12 may be disposed in different metal layers with an insulation layer therebetween. In this case, the heat-conducting metal portion 22 may be disposed on a side of the drain 12 away from the substrate 15, or on a side of the drain 12 facing the substrate 15. The heat-conducting metal portion 22 and the drain 12 may be two adjacent metal layers on the substrate 15, or may be two non-adjacent metal layers. The present disclosure does not limit whether the heat-conducting metal portion 22 and the drain 12 are adjacent. FIG. 19 is a cross-sectional view of a local area of the display panel. FIG. 19 only shows that the drain 12 and the heat-conducting metal portion 22 are disposed on the substrate 15, and does not show the active layer 10 and other metal layers.

When the heat-conducting metal portion 22 and the drain 12 are located in different metal layers, the heat-conducting metal portion 22 and the drain 12 may be in thermal contact with each other through a heat-conducting structure 23. Optionally, the heat-conducting structure 23 may be a through-hole structure filled with heat-conducting material. The heat-conducting material may be any material such as metal, heat-conducting silicone, and graphene.

In some other embodiments, the heat-conducting metal portion 22 and the drain 12 may be located in a same metal layer, and the heat-conducting metal portion 22 and the drain 12 may be integrally formed. The heat in the drain 12 may be conducted to other areas on a same layer through the heat-conducting metal portion 22 on the same layer. Accordingly, the heat dissipation area may be increased, and the heat dissipation efficiency may be improved.

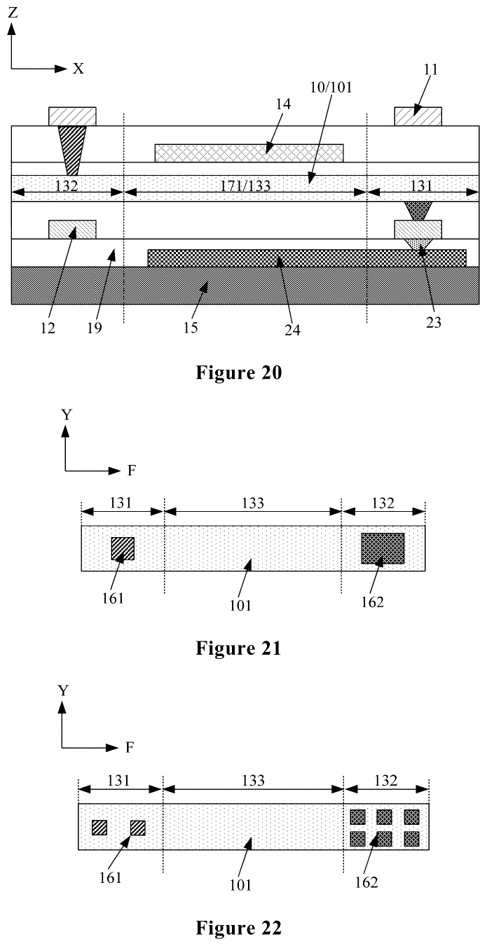

FIG. 20 illustrates a partial cross-sectional view of a drain region of another display panel consistent with the disclosed embodiments of the present disclosure. In the display panel shown in FIG. 20, the gate 14 is disposed on a side of the active branch 101 away from the substrate 15. A light-shielding metal layer 24 is disposed between the active layer 10 and the substrate 15. The light-shielding metal layer 24 is in thermal contact with the drain 12. In this configuration, the gate 14 is disposed on the side of the active branch 101 away from the substrate 15, and the transistor has a top-gate structure. To prevent leakage current from being generated in the channel region due to light incident from the side of the substrate 15, the light shielding metal layer 24 is disposed between the substrate 15 and the active layer 10. In the third direction Z, the light-shielding metal layer 24 overlaps at least a portion of the channel region 133. Accordingly, the channel region 133 may be shielded, and the irradiation on the channel region 133 by light incident from below the substrate 15 may be reduced.

As shown in FIG. 20, in the display panel, the light shielding metal layer 24 is also set to be in thermal contact with the drain 12. The light-shielding metal layer 24 may be multiplexed as a heat-distribution metal layer to conduct the heat in the drain 12 to other areas of the display panel through the light-shielding metal layer 24. As such, heat accumulation in the drain 12 may be avoided, the heat dissipation area may be increased, and the heat dissipation effect may be improved. Since the light shielding metal layer 24 and the drain 12 may be located in different metal layers, thermal contact between the light shielding metal layer 24 and the drain 12 may be achieved through the heat-conducting structure 23. The heat-conducting structure 23 may be a through-hole structure filled with heat-conducting material.

When the light shielding metal layer 24 is set to be in thermal contact with the drain 12, and the light shielding metal layer 24 is multiplexed for heat dissipation, the source 11 and the drain 12 may be respectively prepared from metal layers located on opposite sides of the active layer 10, as shown in FIG. 20. Alternatively, the source 11 and the drain 12 may be simultaneously prepared based on a same metal layer.

In one embodiment, other metal layers in the display panel are set to be in thermal contact with the drain 12, and the other metal layers may be multiplexed for heat dissipation. The relative positions in the display panel of the metal layer where the drain 12 is located and the other metal layers in thermal contact with the drain 12 may be determined according to requirements. The implementation approaches are not limited to the solutions shown in FIGS. 19 and 20. By adjusting the pattern structures in the metal layers according to wiring requirements, thermal contact between the drain 12 and other metal layers may be achieved, on the premise that the source 11 and the drain 12 in the transistor are connected to the active branch 101.

FIG. 21 illustrates a schematic principle diagram of a connection between an active branch and an active layer in a display panel consistent with the disclosed embodiments of the present disclosure. FIG. 21 is a top view of an active branch 101 in the display panel. Referring to FIG. 21, in a same active branch 101, the source terminal 131 may be connected to the source 11 through the first conductive via 161, and the drain terminal 132 may be connected to the drain 12 through the second conductive via 162. The area of the second conductive via 162 is greater than the area of the first conductive via 161. In this way, the source terminal 131 may be connected to the source 11 through the first conductive via 161, and the drain terminal 132 may be connected to the drain 12 through a second conductive via 162. The area of the first conductive via 161 is smaller than the area of the second conductive via 162.

In the embodiment shown in FIG. 21, by setting the area of the second conductive via 162 to be larger than the area of the first conductive via 161, the drain terminal 132 may have a larger thermal contact area with the drain 12. The heat in the drain terminal 132 may be quickly transferred to the drain 12. The drain 12 may be made of metal material and may have relatively large thermal conductivity. As such, heat may be quickly conducted to other areas of the display panel through the drain 12, and heat dissipation performance may be improved.

In some other embodiments, the first conductive via 161 and the second conductive via 162 may have a same area. The conductive vias in the display panel may be prepared based on same size parameters, and the difficulty of the display panel preparation process may be reduced.

FIG. 22 illustrates a schematic principle diagram of a connection between an active branch and an active layer in another display panel consistent with the disclosed embodiments of the present disclosure. FIG. 22 is a top view of an active branch 101 in the display panel. Referring to FIG. 22, in a same active branch 101, the source terminal 131 is connected to the source 11 through a first quantity of first conductive vias 161, and the drain terminal 132 is connected to the drain 12 through a second quantity of second conductive vias 162. The second quantity is greater than the first quantity. The first quantity is equal to or greater than one, the second quantity is greater than one, and the second quantity is greater than the first quantity. The apertures of the first conductive via 161 and the second conductive via 162 may be same. By setting the second quantity to be greater than the first quantity, a larger thermal contact area may be provided between the drain terminal 132 and the drain 12. Accordingly, the heat of the drain terminal 132 may be quickly transferred to the drain 12, and the heat may be prevented from accumulating at the drain terminal 132.

In one embodiment, the width in the first direction Y of the active branch 101 may be uniform and unchanged. That is, the width of the active branch 101 may be uniform along the second direction X. From the source terminal 131 to the drain terminal 132, the widths of the active branch 101 at different positions may be same or approximately same. In the transistor, part of or each of the active branches 101 may have a uniform width in the first direction Y. Accordingly, the manufacturing process of the active branches 101 may be simplified, and the difficulty of the manufacturing process of the display panel may be reduced.

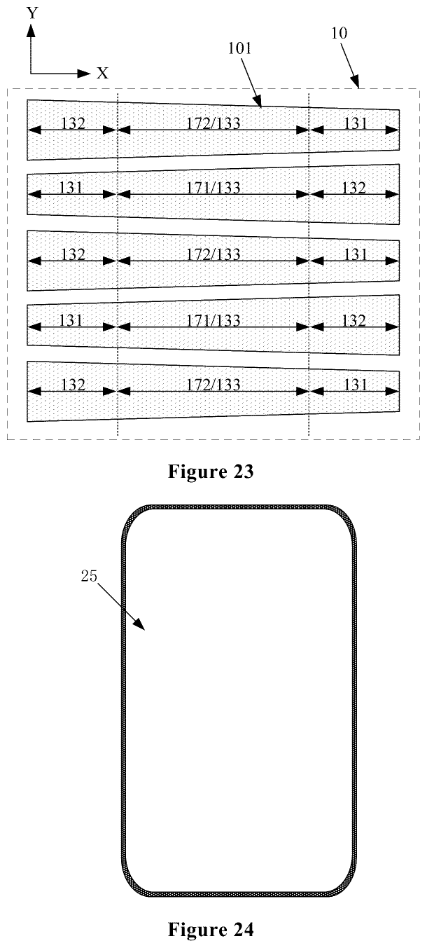

FIG. 23 illustrates a top view of an active layer of a display panel consistent with the disclosed embodiments of the present disclosure. Referring to FIG. 23, in one embodiment, the width of the active branch 101 in the first direction Y may gradually increase along the direction from the source terminal 131 to the drain terminal 132. In one embodiment, as shown in FIG. 23, for each active branch 101 of the active layer 10, the width in the first direction Y gradually increases along the direction from the source terminal 131 to the drain terminal 132. In some other embodiments, for part of the active branches 101 of the active layer 10, the width of the active branches 101 in the first direction Y gradually increases along the direction from the source terminal 131 to the drain terminal 132.

In FIG. 23, the width of the active branch 101 in the first direction Y gradually increases along the direction from the source terminal 131 to the drain terminal 132. The drain terminal of the active branch 101 may be made to have a larger area, such that heat distribution effects may be achieved through a larger area, and the heat may be prevented from accumulating in a small area. In addition, since the drain terminal 132 has a larger area, the drain terminal 132 may have a larger heat conduction area. As such, faster heat conduction from the drain terminal 132 along the third direction Z and the opposite direction of the third direction may be realized. Accordingly, the heat may be faster transferred to other film layers of the display panel, and the heat dissipation effect may be improved.

The present disclosure also provides a display device. FIG. 24 illustrates a schematic structural diagram of a display device consistent with the disclosed embodiments of the present disclosure. Referring to FIG. 24, the display device may include a display panel 25 provided by the present disclosure.

In one embodiment, the display device includes a display panel 25 provided by the present disclosure. The heat dissipation effect of the transistors in the display panel 25 may be improved, and the image display effect of the display device may thus be improved.

Optionally, the display device includes but is not limited to electronic devices with display function, such as mobile phones, tablet computers, laptop computers, and smart wearable devices.

As disclosed, the technical solutions of the present disclosure have the following advantages.

In the display panel and the display device provided by the present disclosure, the active layer includes a plurality of active branches arranged sequentially in the first direction. The active branch includes a source terminal, a drain terminal and a channel region between the source terminal and the drain terminal. Each active branch may form a sub-transistor, and a transistor may thus be divided into a plurality of sub-transistors. As such, the self-heating of the transistor may be reduced, and the heat generated when the transistor is in operation may be reduced. Accordingly, the impact of excessive heat on transistor performance may be avoided, and the image display quality may be improved.

In addition, the plurality of active branches of the active layer includes a first active branch and a second active branch. The direction from the source terminal to the drain terminal in the first active branch and the direction from the source terminal to the drain terminal in the second active branch are opposite, and each are parallel to the second direction. As such, in the second direction, the drain terminals of at least two sub-transistors may be located on different sides of the channel region. As a result, the heat concentration problem caused by the drain terminals of the sub-transistors each being concentrated on a same side of the channel region may be avoided, and the heat dissipation of the transistor may be improved. Accordingly, the influence of excessive heat on the performance of transistors may be avoided, and the image display quality may be improved.

The embodiments disclosed herein are exemplary only and not limiting the scope of the present disclosure. Various combinations, alternations, modifications, equivalents, or improvements to the technical solutions of the disclosed embodiments may be obvious to those skilled in the art. Without departing from the spirit and scope of this disclosure, such combinations, alternations, modifications, equivalents, or improvements to the disclosed embodiments are encompassed within the scope of the present disclosure.

What is claimed is:

1. A display panel, comprising a substrate, an active layer, and a gate, wherein:
the active layer is disposed over a surface of the substrate, and the active layer includes a plurality of active branches sequentially arranged along a first direction, wherein an active branch of the plurality of active branches extends along a second direction, and the first direction and the second direction intersect, and each are parallel to a plane where the substrate is located;
the active branch includes a source terminal, a drain terminal, and a channel region located between the source terminal and the drain terminal, wherein the source terminal is connected to a source, and the drain terminal is connected to a drain;
the gate extends along the second direction, and in a direction perpendicular to the plane where the substrate is located, the gate and the channel region of the active branch have an overlapping portion; and
the plurality of active branches at least includes a first active branch and a second active branch, wherein a direction from the source terminal to the drain terminal of the first active branch is the second direction, and a direction from the source terminal to the drain terminal of the second active branch is an opposite direction of the second direction.

2. The display panel according to claim 1, wherein in the first direction, the plurality of active branches includes:
a first active branch group and a second active branch group arranged in sequence, wherein the first active branch group includes one or more first active branch of the first active branch, and the second active branch group includes one or more second active branch of the second active branch; or
a plurality of first active branch groups and a plurality of second active branch groups that are alternately arranged, wherein a first active branch group of the plurality of first active branch groups includes one or more first active branch of the first active branch, and a second active branch group of the plurality of second active branch groups includes one or more second active branch of the second active branch.

3. The display panel according to claim 2, wherein:
the first active branch group includes one first active branch of the first active branch, and the second active branch group includes one second active branch of the second active branch.

4. The display panel according to claim 1, wherein:
the gate is disposed on a first metal layer, the drain is disposed on a second metal layer, the source is disposed on a third metal layer, and the active layer is disposed between the second metal layer and the third metal layer;
the drain includes a first drain trace and a second drain trace sequentially arranged along the second direction, and the source includes a first source trace and a second source trace sequentially arranged along the second direction;
in a direction parallel to the plane where the substrate is located, the gate is disposed between the first drain trace and the second drain trace, and between the first source trace and the second source trace; and
in the first active branch, the source terminal is connected to the first source trace, and the drain terminal is connected to the second drain trace; and in the second active branch, the source terminal is connected to the second source trace, and the drain terminal is connected to the first drain trace.

5. The display panel according to claim 4, wherein:
the first metal layer is disposed between the third metal layer and the active layer; or the second metal layer is disposed between the substrate and the active layer; or the second metal layer is disposed on a side of the active layer away from the substrate.

6. The display panel according to claim 4, wherein:
in the direction perpendicular to the plane where the substrate is located, the first source trace is vertically opposite to the first drain trace, and the second source trace is vertically opposite to the second drain trace.

7. The display panel according to claim 4, wherein:
one or more first insulation layer is disposed between the second metal layer and the active layer, and one or more second insulation layer is disposed between the third metal layer and the active layer, wherein thermal conductivity of a first insulation layer of the one or more first insulation layer is greater than thermal conductivity of a second insulation layer of the one or more second insulation layer.

8. The display panel according to claim 1, wherein:
the gate is disposed on a first metal layer, and the source and the drain each are disposed on a second metal layer;
one of the source and the drain includes a first trace and a second trace arranged in sequence in the second direction, and another of the source and the drain includes a third trace located between the first trace and the second trace;
in a direction parallel to the plane where the substrate is located, the gate is disposed between the first trace and the second trace;
when the source includes the first trace and the second trace, the source terminal of the first active branch is connected to the first trace, and the source terminal of the second active branch is connected to the second trace; and
when the drain includes the first trace and the second trace, the drain terminal of the first active branch is connected to the second trace, and the drain terminal of the second active branch is connected to the first trace.

9. The display panel according to claim 8, wherein:
the drain includes the first trace and the second trace, and the source includes the third trace.

10. The display panel according to claim 8, wherein:
the third trace includes a plurality of first comb teeth sequentially arranged along the first direction on a side of the third trace facing the first trace, and a plurality of second comb teeth sequentially arranged along the first direction on a side of the third trace facing the second trace;
when the drain includes the third trace, the drain terminal of the first active branch is connected to the third trace through a comb tooth of the plurality of second comb teeth, and the drain terminal of the second active branch is connected to the third trace through a comb tooth of the plurality of first comb teeth; and
when the source includes the third trace, the source terminal of the first active branch is connected to the third trace through the comb tooth of the plurality of first comb teeth, and the source terminal of the second active branch is connected to the third trace through the comb tooth of the plurality of second comb teeth.

11. The display panel according to claim 10, wherein:
the third trace has a first width d1 in the second direction;
the plurality of first comb teeth and the plurality of second comb teeth each have a second width d2 in the first direction; and
the active branch has a third width d3 in the first direction,
wherein: d1>d3>d2.

12. The display panel according to claim 8, wherein:
the third trace is disposed on a side of the gate away from the active layer, wherein in the direction perpendicular to the plane where the substrate is located, the third trace and the gate have an overlapping portion.

13. The display panel according to claim 1, wherein:
in a same active branch of the plurality of active branches, the source terminal has a first area, and the drain terminal has a second area, wherein the second area is greater than the first area.

14. The display panel according to claim 1, wherein:
an area of the drain is larger than an area of the source.

15. The display panel according to claim 1, wherein:
a plurality of metal layers is sequentially stacked on a same side of the substrate; and
one or more metal layer of the plurality of metal layers includes a heat-conducting metal portion, and the heat-conducting metal portion is in thermal contact with the drain.

16. The display panel according to claim 1, wherein:
the gate is disposed on a side of the active branch away from the substrate; and
a light-shielding metal layer is disposed between the active layer and the substrate, wherein the light-shielding metal layer is in thermal contact with the drain.

17. The display panel according to claim 1, wherein:
in a same active branch of the plurality of active branches, the source terminal is connected to the source through a first conductive via, and the drain terminal is connected to the drain through a second conductive via, wherein an area of the second conductive via is greater than an area of the first conductive via.

18. The display panel according to claim 1, wherein:
in a same active branch of the plurality of active branches, the source terminal is connected to the source through a first quantity of first conductive vias, and the drain terminal is connected to the drain through a second quantity of second conductive vias, wherein the second quantity is greater than the first quantity.

19. The display panel according to claim 1, wherein:
along the second direction, each of the plurality of active branches has a uniform width in the first direction; or
a width of the active branch in the first direction increases along the direction from the source terminal to the drain terminal.

20. A display device, including a display panel, wherein the display panel includes a
substrate, an active layer, and a gate, wherein:
the active layer is disposed over a surface of the substrate, and the active layer includes a plurality of active branches sequentially arranged along a first direction, wherein an active branch of the plurality of active branches extends along a second direction, and the first direction and the second direction intersect, and each are parallel to a plane where the substrate is located;
the active branch includes a source terminal, a drain terminal, and a channel region located between the source terminal and the drain terminal, wherein the source terminal is connected to a source, and the drain terminal is connected to a drain;
the gate extends along the second direction, and in a direction perpendicular to the plane where the substrate is located, the gate and the channel region of the active branch have an overlapping portion; and
the plurality of active branches at least includes a first active branch and a second active branch, wherein a direction from the source terminal to the drain terminal of the first active branch is the second direction, and a direction from the source terminal to the drain terminal of the second active branch is an opposite direction of the second direction.
